(19) United States
(12) Patent Application Publication
(10) Pub. No.: US 2006/0087041 A1
(43) Pub. Date: Apr. 27, 2006

(54) Semiconductor device

(75) Inventors: Shun-ichi Fukuyama, Kawasaki (JP); Tamotsu Owada, Kawasaki (JP); Hiroko Inoue, Yamato (JP); Ken Sugimoto, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/256,681

(22) Filed: Oct. 24, 2005

Related U.S. Application Data
(63) Continuation of application No. PCT/JP03/11001, filed on Aug. 28, 2003.

(51) Int. Cl. H01L 23/48

(52) U.S. Cl. 257/774

(57) ABSTRACT

A semiconductor device is disclosed that includes a substrate, a first wiring structure arranged on the substrate which first wiring structure includes a first insulating layer and a first wiring layer arranged within the first insulating layer, a second wiring structure arranged on the first wiring structure which second wiring structure includes a second insulating layer including a shock absorbing layer made of an insulating film and a second wiring layer arranged within the second insulating layer, and a third wiring structure arranged on the second wiring structure which third wiring structure includes a third insulating layer and a third wiring layer arranged within the third insulating layer. The fracture toughness value of the shock absorbing layer is arranged to be greater than the fracture toughness value of the first insulating film and the fracture toughness value of the third insulating film.

### CROSS REFERENCE TO RELATED APPLICATIONS

This application is a U.S. continuation application filed under 35 USC 111 (a) claiming benefit under 35 USC 120 and 365(c) of PCT application JP2003/011001, filed Aug. 28, 2003, which is incorporated herein by reference in its entirety.

### BACKGROUND OF THE INVENTION

1. Field of the Invention

The present invention relates to a semiconductor device having a multi-layered wiring structure.

2. Description of the Related Art

The operating speed of a semiconductor device may be increased through its miniaturization according to the scaling rule. In a high density semiconductor integrated circuit device, a multi-layer wiring structure is generally used to realize wiring between the individual semiconductor devices. In such a multi-layer wiring structure, when the semiconductor device is miniaturized, the wiring patterns within the multi-layer wiring structure may close in on each other to thereby cause wiring delay due to parasitic capacitance between the wiring patterns. The parasitic capacitance is inversely proportional to the distance between the wiring patterns, and proportional to the dielectric constant of the insulating film arranged between the wiring patterns.

When a CVD-SiO₂ film or a SiOF film, which is obtained by doping fluorine into the CVD-SiO₂ film, is used as the insulating film between the wiring patterns (inter-wiring insulating film), the dielectric constant of the insulating film may be within a range of approximately 3.3 to 4.0. However, a lower dielectric constant is desired.

In this respect, an organic insulating film that may be formed through spin coating, for example, and is capable of realizing a lower dielectric constant within a range of approximately 2.3 to 2.5 is being contemplated for use as the inter-wiring insulating film; namely, the inter-layer insulating film, of a semiconductor device.

FIG. 1 is a cross-sectional view of a semiconductor device 100 that uses an organic insulating film as the inter-layer insulating film.

As is shown in FIG. 1, the semiconductor device 100 includes a Si substrate 101, a device isolation insulating film 102 arranged on the Si substrate 101 for isolating a device region, a gate insulating film 104A that is arranged on the device region isolated by the device isolation insulating film 102, a gate electrode 104 that is arranged on the gate insulating film 104A, and diffusion layers 105A and 105B that are arranged at the sides of the gate electrode 104.

The side wall surfaces of the gate electrode 104 are covered by side wall insulating films 103A and 103B, and an inter-plug insulating film 106 that is made of a PSG film (phosphosilicate glass film) is arranged on the Si substrate 101 to cover the gate electrode 104 and the side wall insulating films 103A and 103B. Also, a protective film 107 is arranged on the inter-plug insulating film 106.

At the inter-plug insulating film 106 and the protective film 107, a contact hole connected to the dispersion layer 105B is created, and a barrier film 108 is arranged at the inner wall of this contact hole. Further, a contact plug 109 that is made of W (tungsten), for example, is arranged within the contact hole having the barrier film 108 arranged on its inner wall. The contact plug 109 is electrically connected to the dispersion layer 105B via the barrier film 108.

An inter-wiring insulating film 110 that is made of an organic insulating film, for example, is arranged on the protective film 107, and a cap film 111 is arranged on the inter-wiring insulating film 110.

A wiring trench is formed through etching at the inter-wiring insulating film 110 and the cap film 111, and Cu wiring 112 and a barrier film 112a surrounding the Cu wiring 112 are arranged at the wiring trench. The Cu wiring 112 is electrically connected to the contact plug 109 via the barrier film 112a.

A protective film 113 is arranged on the cap film 111 and the Cu wiring 112, and an inter-plug insulating film 114 that is made of an organic film, for example, is arranged on the protective film 113. Further, a protective film 115 is arranged on the inter-plug insulating film 114.

A via hole is formed through etching at the protective film 113, the inter-plug insulating film 114, and the protective film 115, and a Cu plug 118 and a barrier film 118a surrounding the Cu plug 118 are arranged at the via hole. The Cu plug 118 is electrically connected to the Cu wiring 112 via the barrier film 118a.

An inter-wiring insulating film 116 that is made of an organic insulating film, for example, is arranged on the protective film 115, and a cap film 117 is arranged on the inter-wiring insulating film 116.

A wiring trench is formed through etching at the inter-wiring insulating film 116 and the cap film 117, and Cu wiring 119 and a barrier film 119a surrounding the Cu wiring 119 are arranged at the wiring trench. The Cu wiring 119 is connected to the Cu plug 118.

In this way, a wiring structure 120 made up of the protective film 113, the inter-plug insulating film 114, the protective film 115, the inter-wiring insulating film 116, the cap film 117, the Cu plug 118, the Cu wiring 119, the barrier film 118a and the barrier film 119a, for example, may be constructed and arranged on the Cu wiring 112.

As can be appreciated from the above descriptions, an organic insulating film having a low dielectric constant is used as the inter-wiring insulating film and the inter-plug insulating film of the semiconductor device 100, and thereby, the semiconductor device 100 may be operated at a relatively high speed (e.g., see Japanese Laid-Open Patent Publication No. 2003-31566 and Japanese Laid-Open Patent Publication No. 2002-124513).

However, a high performance semiconductor device used these days requires an even higher operating speed. In such a semiconductor device, there may be strict requirements against wiring delay so that an insulating film with an even lower dielectric constant is desired as the inter-layer insulating film.

In this respect, for example, a porous insulating film, which is capable of realizing a lower dielectric constant, may be used as the inter-layer insulating film. A porous insulating film includes plural holes in order to lower its dielectric constant.

However, when the porous insulating film is used in place of the organic insulating film in the semiconductor device 100 shown in FIG. 1, the following problems may arise.

Since the porous insulating film includes plural holes, it may not have adequate mechanical strength, for example. Accordingly, when a crack is generated at the porous insulating film, the porous insulating film may break. Also, the porous insulating film may exfoliate from adjacent films to which it is attached, for example.

### SUMMARY OF THE INVENTION

The present invention provides a semiconductor device that is capable of resolving one or more of the problems described above.

More specifically, the present invention provides a semiconductor device having a multi-layered wiring structure that is capable of preventing breakage and exfoliation of one or more inter-layer insulating films of the semiconductor device and realizing high-speed/stable operations.

According to an embodiment of the present invention, a semiconductor device is provided that includes:
a substrate;
a first wiring structure arranged on the substrate which first wiring structure includes a first insulating layer and a first wiring layer arranged within the first insulating layer;
a second wiring structure arranged on the first wiring structure which second wiring structure includes a second insulating layer including a shock absorbing layer made of an insulating film and a second wiring layer arranged within the second insulating layer; and
a third wiring structure arranged on the second wiring structure which third wiring structure includes a third insulating layer and a third wiring layer arranged within the third insulating layer;
wherein the fracture toughness value of the shock absorbing layer is greater than the fracture toughness value of the first insulating film and the fracture toughness value of the third insulating film.

According to another embodiment of the present invention, a semiconductor device is provided that includes:
a substrate;
a first wiring structure arranged on the substrate which first wiring structure includes a first insulating layer and a first Cu wiring layer arranged within the first insulating layer; and
a second wiring structure arranged on the first wiring structure which second wiring structure includes a second insulating layer including a shock absorbing layer made of an insulating film and a second Cu wiring layer arranged within the second insulating layer;
wherein the fracture toughness value of the shock absorbing layer is greater than the fracture toughness value of the first insulating layer.

### BRIEF DESCRIPTION OF THE DRAWINGS

FIG. 1 is a cross-sectional view of a semiconductor device having a multi-layered wiring structure;

FIG. 2 is a cross-sectional view of a semiconductor device having a multi-layered wiring structure according to a first embodiment of the present invention;

FIG. 3 is a diagram showing the wiring pitches of wiring structures of the semiconductor device shown in FIG. 2;

FIG. 4 is a cross-sectional view of a semiconductor device corresponding to a first modification example of the semiconductor device shown in FIG. 2;

FIG. 5 is a cross-sectional view of a semiconductor device corresponding to a second modification example of the semiconductor device shown in FIG. 2;

FIG. 6 is a cross-sectional view of a semiconductor device corresponding to a third modification example of the semiconductor device shown in FIG. 2;

FIGS. 7A through 7P are diagrams showing the steps for fabricating the semiconductor device shown in FIG. 2; and

FIGS. 8A through 8P are diagrams showing the steps for fabricating the semiconductor device shown in FIG. 6.

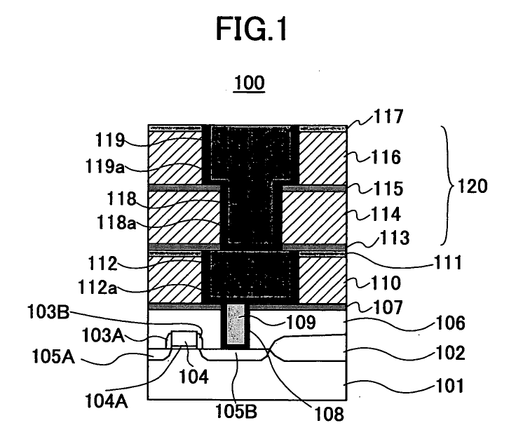

### DESCRIPTION OF THE PREFERRED EMBODIMENTS

In the following, preferred embodiments of the present invention are described with reference to the accompanying drawings.

### First Embodiment

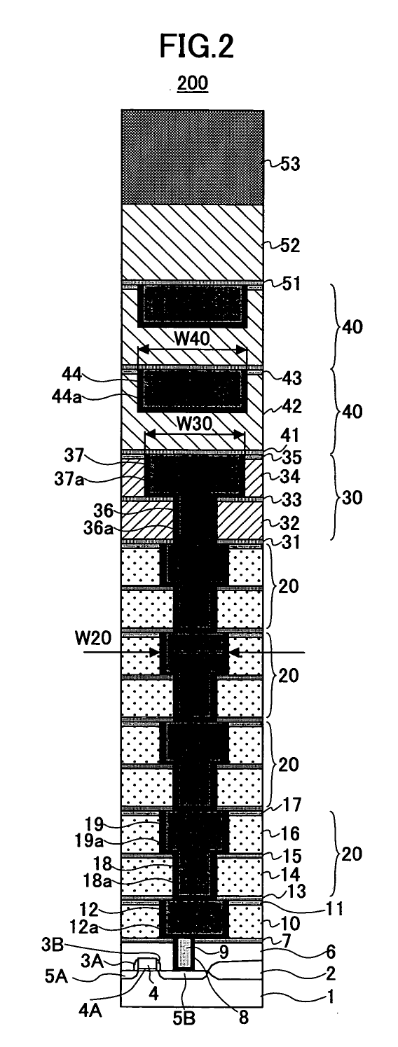

FIG. 2 is a cross-sectional view of a semiconductor device 200 that uses an insulating film with a low dielectric constant such as a porous insulating film as an inter-layer insulating film to reduce the influence of wiring delay and increase the operating speed.

According to the present embodiment, high speed operation of the semiconductor device 200 is realized by forming inter-layer films including an inter-wiring insulating layer and an inter-plug insulating film with a porous insulating film, for example, to lower the dielectric constant of the inter-layer films, decrease the parasitic capacitance between wirings, and reduce the influence of wiring delay.

As is shown in FIG. 2, the semiconductor 200 includes a Si substrate 1, a device isolation insulating film 2 arranged on the Si substrate 1 for isolating a device region, a gate insulating film 4A that is arranged on the device region isolated by the device isolation insulating film 2, a gate electrode 4 that is arranged on the gate insulating film 4A, and diffusion layers 5A and 5B that are arranged at the sides of the gate electrode 4.

The side wall surfaces of the gate electrode 4 are covered by side wall insulating films 3A and 3B, and an inter-plug insulating film 6 that is made of a PSG film (phosphosilicate glass film) is arranged on the Si substrate 1 to cover the gate electrode 4 and the side wall insulating films 3A and 3B. Also, a protective film 7 is arranged on the inter-plug insulating film 6.

At the inter-plug insulating film 6 and the protective film 7, a contact hole connected to the dispersion layer 5B is formed, and a barrier film 8 is arranged at the inner wall of this contact hole. Further, a contact plug 9 that is made of W (tungsten), for example, is arranged within the contact hole having the barrier film 8 covering its inner wall. The contact plug 9 is electrically connected to the dispersion layer 5B via the barrier film 8.

An inter-wiring insulating film 10 that is made of an organic insulating film, for example, is arranged on the protective film 7, and a cap film 11 is arranged on the inter-wiring insulating film 10.

A wiring trench is formed through etching at the inter-wiring insulating film 10 and the cap film 11, and Cu wiring 12 and a barrier film 12a surrounding the Cu wiring 12 are arranged at the wiring trench. The Cu wiring 12 is electrically connected to the contact plug 9 via the barrier film 12a.

A protective film 13 is arranged on the cap film 11 and the Cu wiring 12, and an inter-plug insulating film 14 that is made of an organic film, for example, is arranged on the protective film 13. Further, a protective film 15 is arranged on the inter-plug insulating film 14.

A via hole is formed through etching at the protective film 13, the inter-plug insulating film 14, and the protective film 15, and a Cu plug 18 and a barrier film 18a surrounding the Cu plug 18 are arranged at the via hole. The Cu plug 18 is electrically connected to the Cu wiring 12 via the barrier film 18a.

An inter-wiring insulating film 16 that is made of an organic insulating film, for example, is arranged on the protective film 15, and a cap film 17 is arranged on the inter-wiring insulating film 16.

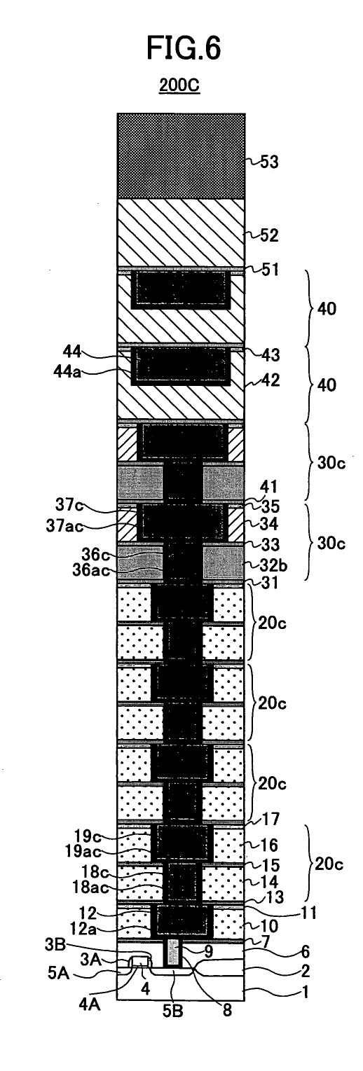

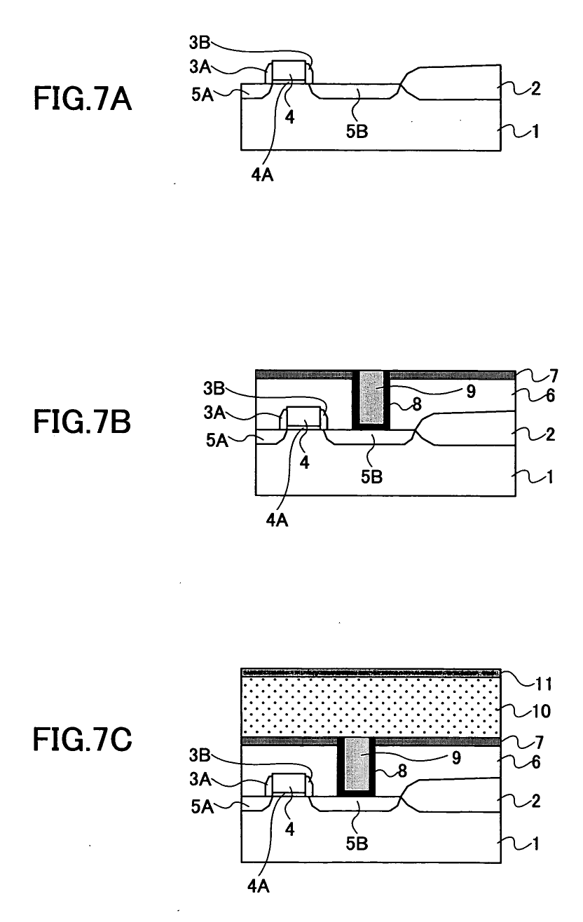

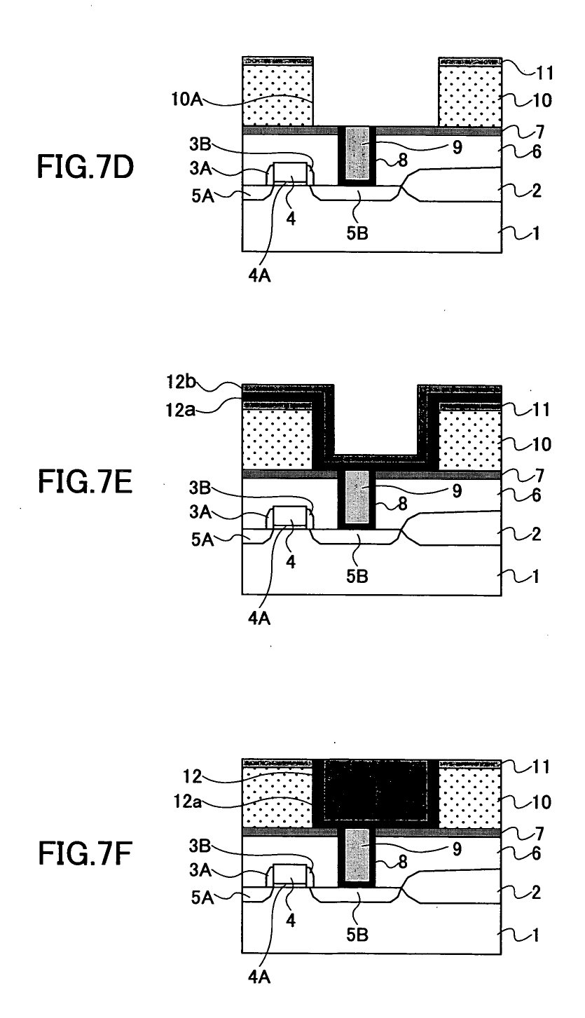

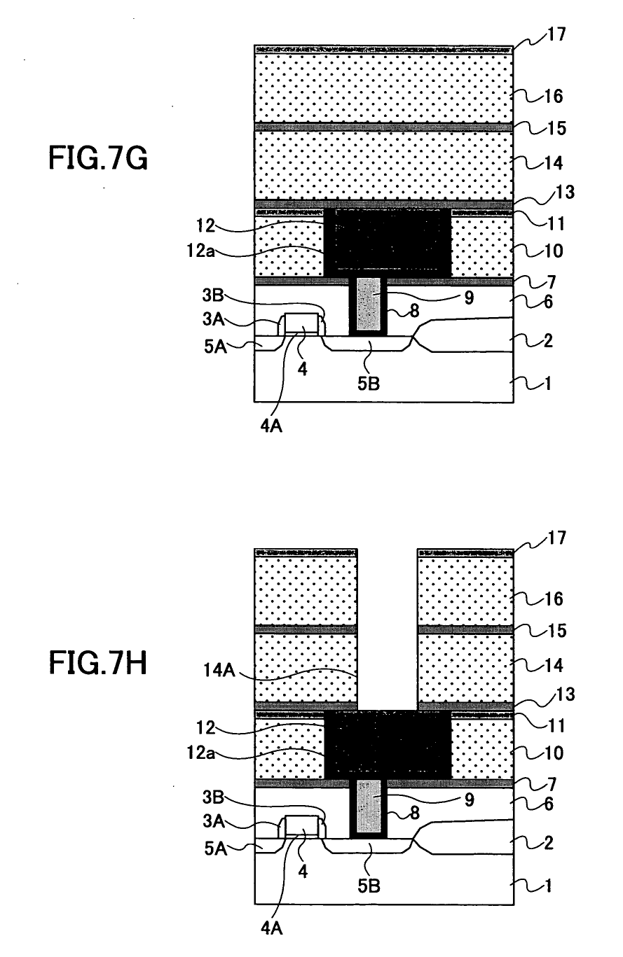

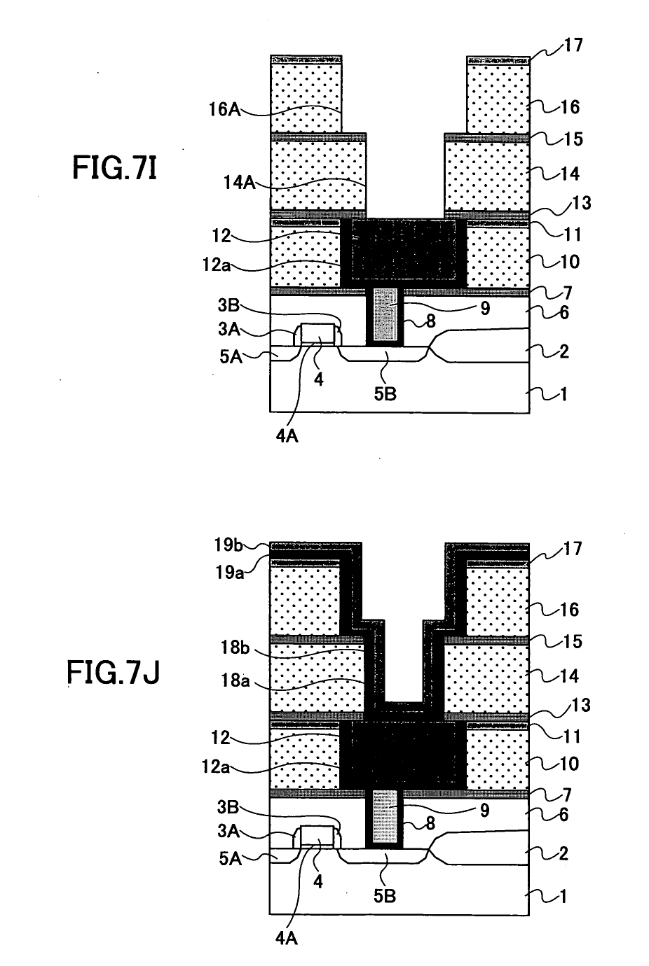

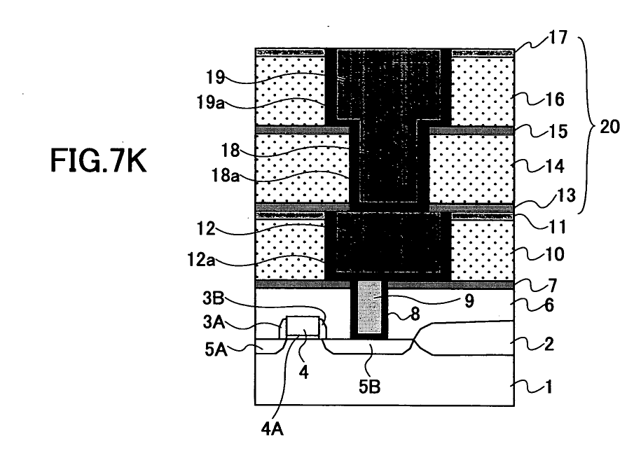

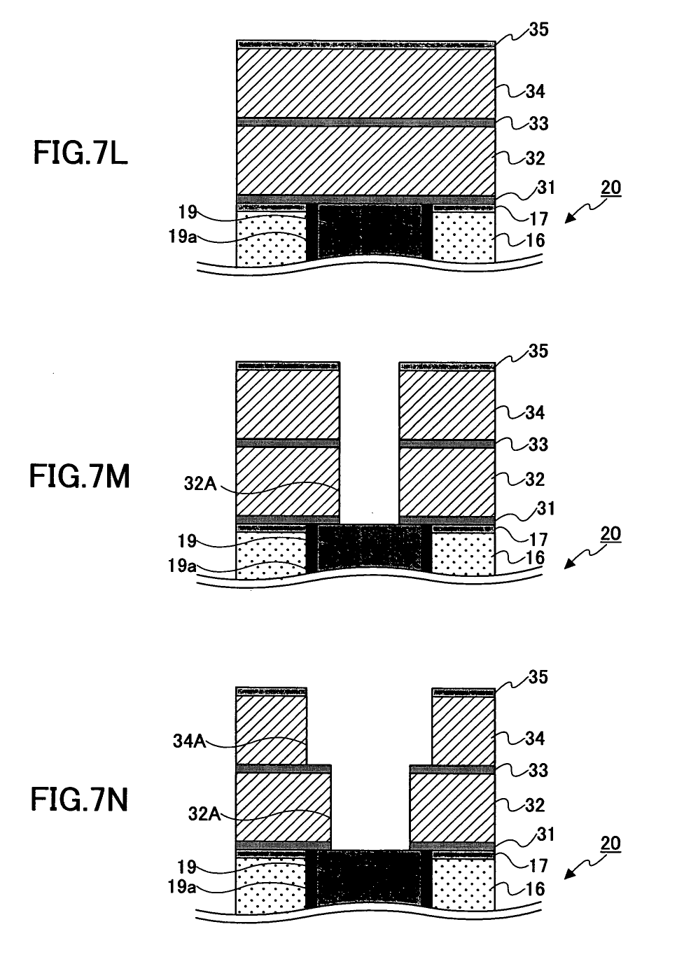

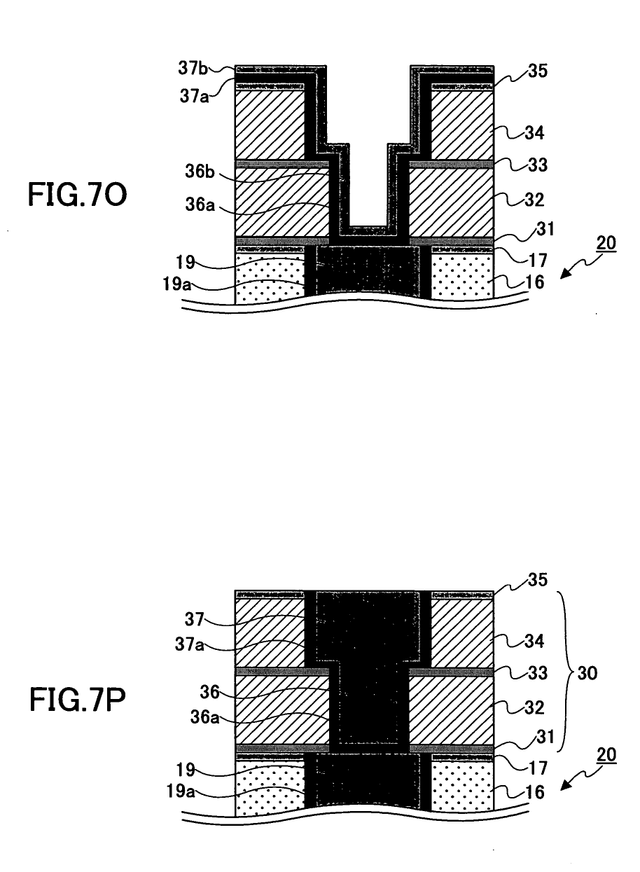

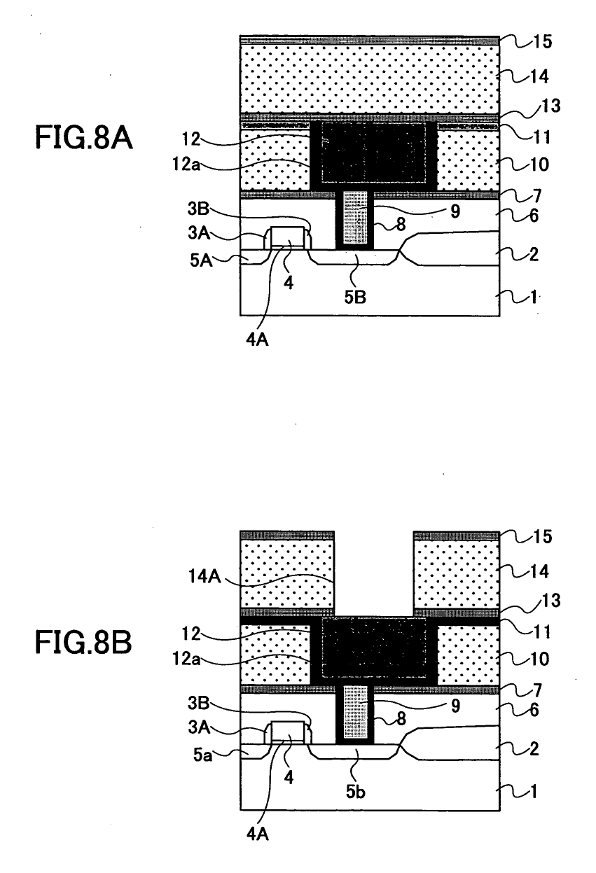

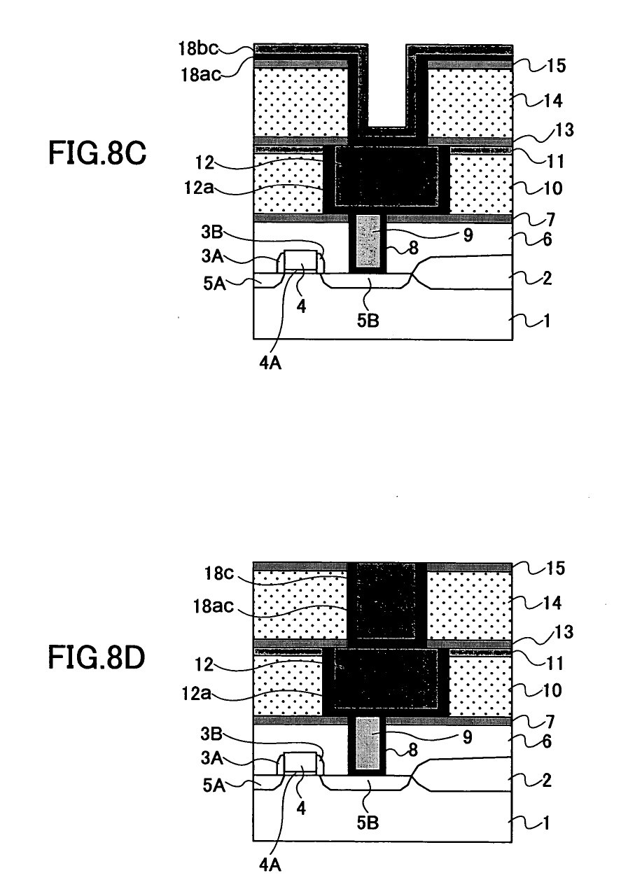

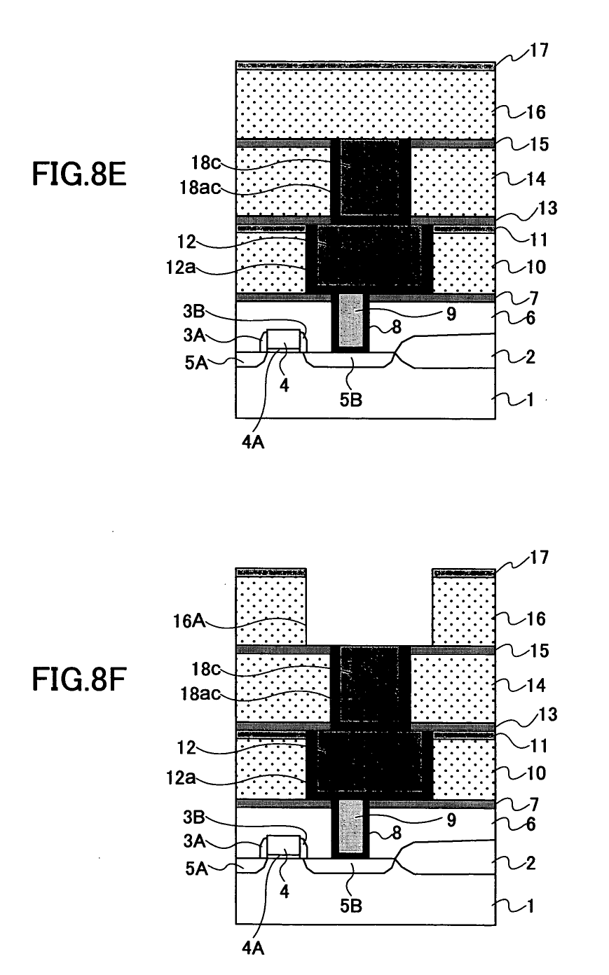

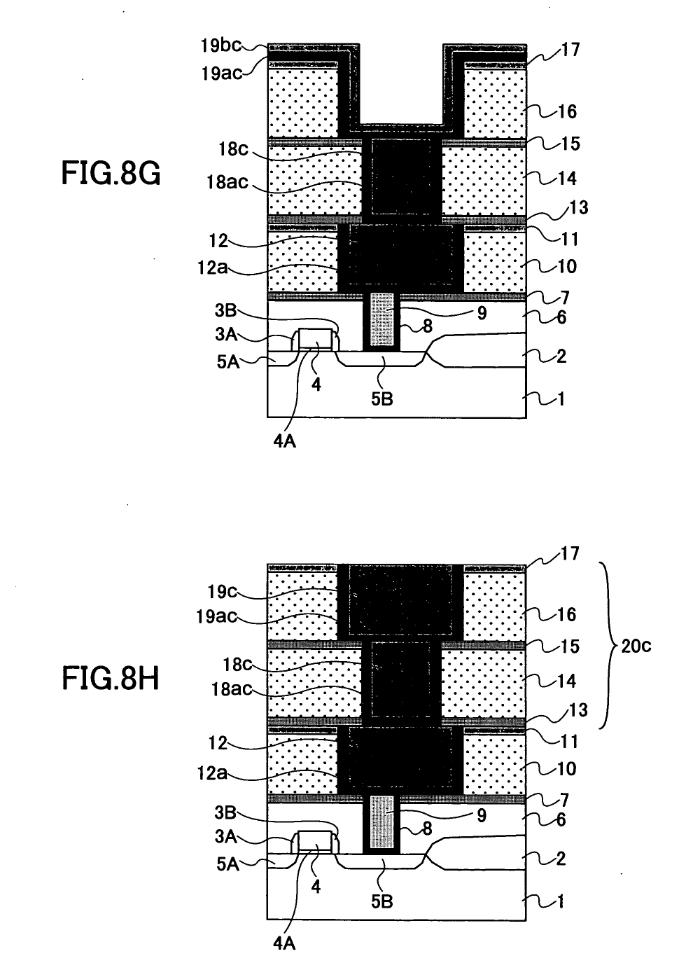

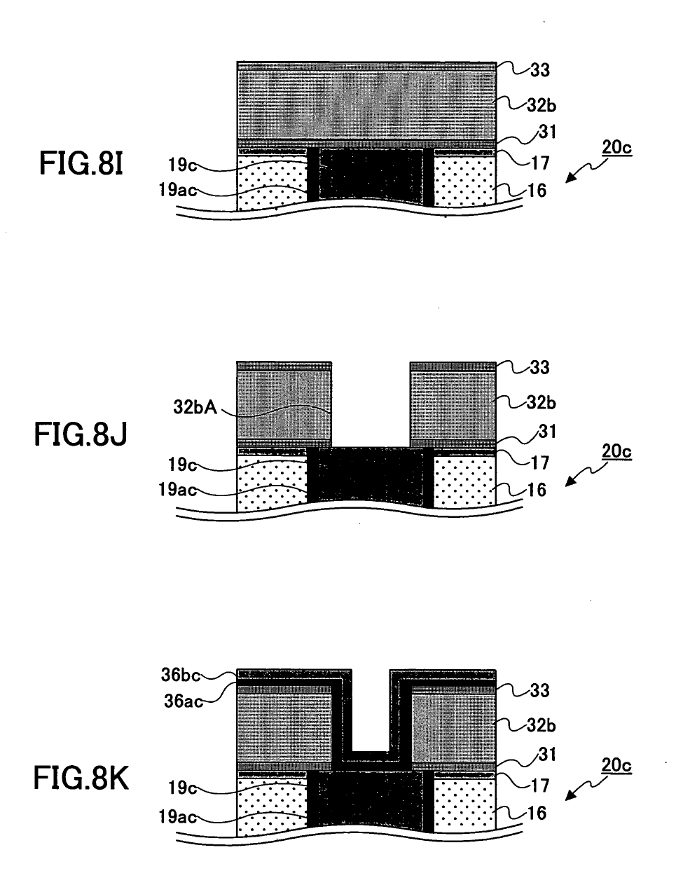

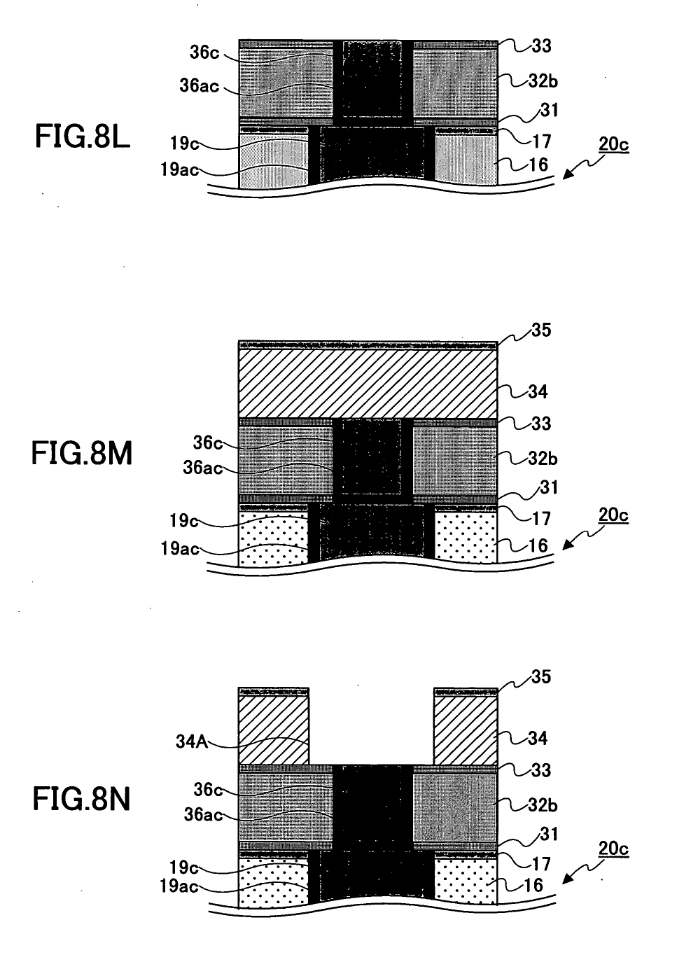

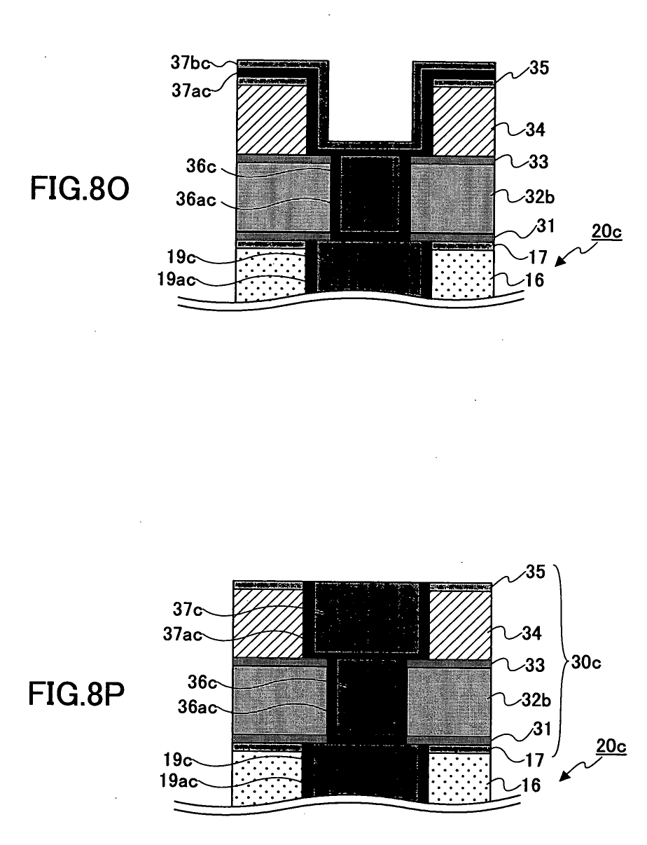

A wiring trench is formed through etching at the inter-wiring insulating film 16 and the cap film 17, and Cu wiring 19 and a barrier film 19a surrounding the Cu wiring 19 are arranged at the wiring trench. The Cu wiring 19 is connected to the Cu plug 18. It is noted that the Cu wiring 19 and the Cu plug 18 may be formed simultaneously through the so-called dual damascene method, for example, as is described below with reference to FIGS. 7A through 7P. In another example, the Cu wiring 19 and the Cu plug 18 may be formed through the so-called single damascene method as is described below with reference to FIG. 6 and FIGS. 8A through 8P.

In this way, a wiring structure 20 made up of the protective film 13, the inter-plug insulating film 14, the protective film 15, the inter-wiring insulating film 16, the cap film 17, the Cu plug 18, the Cu wiring 19, the barrier film 18a and the barrier film 19a, for example, may be constructed and arranged on the Cu wiring 12. In the semiconductor device 200 shown in FIG. 2, four layers of the wiring structure 20 are arranged on the Cu wiring 12 to realize a five-layer Cu wiring structure.

Also, a wiring structure 30 having a configuration similar to that of the wiring structure 20 is arranged on the uppermost wiring structure 20 of the multi-layered wiring structures 20; namely, the wiring structure 20 that is positioned furthest from the Si substrate 1.

It is noted that in the present embodiment, the inter-layer insulating films of the wiring layer made up of the Cu wiring and the Cu plug are arranged to have higher fracture toughness values compared to the inter-layer insulating films of the wiring structure 20. Therefore, for example, when stress is applied to the semiconductor device 200, the inter-layer insulating films with the higher fracture toughness values may act as shock absorbing layers to reduce the impact of the stress applied to the semiconductor device 200.

The wiring structure 30 has a configuration as is described below. First, a protective film 31 is arranged on the cap film 17 and the Cu wiring 19, and an inter-plug insulating film 32 made of an organic insulating film with a high fracture toughness value, for example, is arranged on the protective film 31, and a protective film 33 is arranged on the inter-plug insulating film 32.

A via hole is formed through etching at the protective film 31, the inter-plug insulating film 32, and the protective film 33, and a Cu plug 36 and a barrier film 36a surrounding the Cu plug 36 are arranged in the via hole. The Cu plug 36 is electrically connected to the Cu wiring 19 via the barrier film 36a.

An inter-wiring insulating film 34 that is made of an organic insulating film with a high fracture toughness value, for example, is arranged on the protective film 33, and a cap film 35 is arranged on the inter-wiring insulating film 34.

A wiring trench is formed through etching at the inter-wiring insulating film 34 and the cap film 35, and Cu wiring 37 and a barrier film 37a surrounding the Cu wiring 37 are arranged in the wiring trench. The Cu wiring 37 is connected to the Cu plug 36. It is noted that the Cu wiring 37 and the Cu plug 36 may be formed simultaneously through the so-called dual damascene method, for example, as is described below with reference to FIGS. 7A through 7P. In another example, the Cu wiring 37 and the Cu plug 36 may be formed through the so-called single damascene method as is described below with reference to FIG. 6 and FIGS. 8A through 8P.

In this way, the wiring structure 30 that is made up of the protective film 31, the inter-plug insulating film 32, the protective film 33, the inter-wiring insulating film 34, the cap film 35, the Cu plug film 36, the Cu wiring 37, the barrier film 36a, and the barrier film 37a, for example, may be constructed and arranged on the wiring structure 20.

According to the present embodiment, the insulating film used in the wiring structure 30 is arranged to have a fracture toughness value that is greater than that of the insulating film used in the wiring structure 20. Therefore, when stress is applied to the semiconductor device 200, for example, the inter-plug insulating film 32 and/or the inter-wiring insulating film 34 may deform from the stress but not break owing to its high fracture toughness value to thereby act as a shock absorbing layer that can reduce the impact of the stress.

In turn, the inter-layer insulating films of the wiring structure 20; that is, the inter-plug insulating film 14, the inter-wiring insulating film 16, and/or the inter-plug insulating film 10, for example, may be prevented from breaking from the impacts of the stress.

Also, the inter-plug insulating film 14, the inter-wiring insulating film 16, and/or the inter-plug insulating film 10 may be prevented from exfoliating from the wiring structure, for example, so that a stable semiconductor device may be realized.

It is noted that an insulating film with a low dielectric constant generally has relatively low mechanical strength. For example, the mechanical strength of a porous insulating film is particularly low since it has plural holes, and thereby it may easily break upon having stress applied thereto.

For example, in a process of fabricating the semiconductor device such as a CMP (Chemical Mechanical Polishing) process in which stress is applied and/or a thermal process in which stress from thermal contraction is generated, the porous insulating film with low mechanical strength may be prone to breaking. Also, the porous insulating film may be prone to breaking from stress applied thereto upon forming pads on the semiconductor device and connecting wires through wire bonding.

However, in a semiconductor device that requires high operating speed, the influence of wiring delay is preferably controlled so that the parasitic capacitance between wirings may be reduced. In this respect, use of the porous insulating film may be beneficial for reducing the dielectric constant of the inter-layer insulating film.

In the present embodiment, an insulating film such as a porous insulating film that has low mechanical strength and is easily breakable may be adequately protected from breakage and/or exfoliation so that a semiconductor device that uses an insulating film with a low dielectric constant and little wiring delay may be realized.

In a preferred embodiment, an organic film is used for the inter-plug insulating film 32 and the inter-wiring insulating film 34. An organic film has a dielectric constant that is lower than that of a SiOC film or a SiO₂ film, and thereby, the inter-wiring parasitic capacitance may be reduced.

In another preferred embodiment, the width W30 of the Cu wiring 37 within the wiring structure 30 is arranged to be wider than the width W20 of the Cu wiring 19 within the wiring structure 20, and the distance between adjacent Cu wirings 37 (not shown in FIG. 2) of the wiring structure 30 is arranged to be greater than the distance between adjacent wirings 19 (not shown) of the wiring structure 20. By using an organic insulating film as the inter-layer insulating film in the wiring structure 30, a desired dielectric constant of the inter-layer insulating film may be achieved in the wiring structure 30.

Also, two layers of global wiring structures 40 may be arranged on the wiring structure 30, for example. The global wiring structure 40 includes a protective film 41, an inter-layer insulating film 42 made of a SiO₂ film that is arranged on the protective film 41, and Cu wiring 44 and a barrier film 41a that are arranged within the inter-layer insulating film 41. It is noted that in the illustrated example, the via plug portion of the global wiring structure 40 is not shown.

In a preferred embodiment, the wiring width W40 of the wiring structure 40 is arranged to be wider than the wiring width W30 of the wiring structure 30, and the distance between adjacent wirings of the wiring structure 40 is arranged to be greater than that of the wiring structure 30.

In the illustrated example, a cap film 52 that is made of a SiO₂ film is arranged on the dual-layer global wiring structure 40 via a protective film 51, and a pad portion 53 that is made of Al, for example, is arranged on the cap film 52. Also, a bonding wire is connected to the pad portion 53 through a wire bonding process. It is noted that in the wire bonding process, stress is applied to the semiconductor device 200; however, since a wiring structure including an insulating film with a high fracture toughness value is used in the present embodiment, the impact of stress may be reduced, and the inter-layer insulating film made of a porous insulating film having a low dielectric constant may be prevented from breaking.

As can be appreciated from the above descriptions, a porous film with a low dielectric constant may be used as the inter-wiring insulating film and the inter-plug insulating film in the semiconductor device 200 according to the present embodiment, and thereby, the inter-wiring parasitic capacitance may be reduced and the influence of wiring delay may be reduced so that a high operating speed may be realized in the semiconductor device 200.

It is noted that in the illustrated example, a porous silica film is used as the porous insulating film realizing the inter-wiring insulating film 10, the inter-plug insulating film 14, and the inter-wiring insulating film 16 so that the dielectric constant of the inter-layer insulating films may be arranged to be within a range of approximately 2.0 to 2.5.

In alternative embodiments, a porous SiO₂ film or a porous organic film may be used instead of the porous silica film to obtain similar effects as is described above.

In further alternative embodiments, other various types of porous insulating films such as a porous SiOC film or a porous SiOF film may be used as the inter-layer insulating film with a low dielectric constant.

Also, in the illustrated example, an insulating film including allyl ester is used as the organic insulating film realizing the inter-layer film of the wiring structure 30; namely, the inter-plug insulating film 32 and/or the inter-wiring insulating film 34. It is noted that the fracture toughness value of allyl ester is approximately within a range of 20 to 30 which is greater than the fracture toughness value of the porous silica film used in the wiring structure 20 or the fracture toughness value of the SiO₂ film (approximately within a range of 5 to 10) used in the global wiring structure 40. In the present embodiment, the inter-layer insulating film of the wiring structure 30 may act as a shock absorbing layer.

In alternative embodiments, other types of organic insulating films such as an insulating film including benzocyclobutene instead of ally ester may be used to obtain similar effects as is described above.

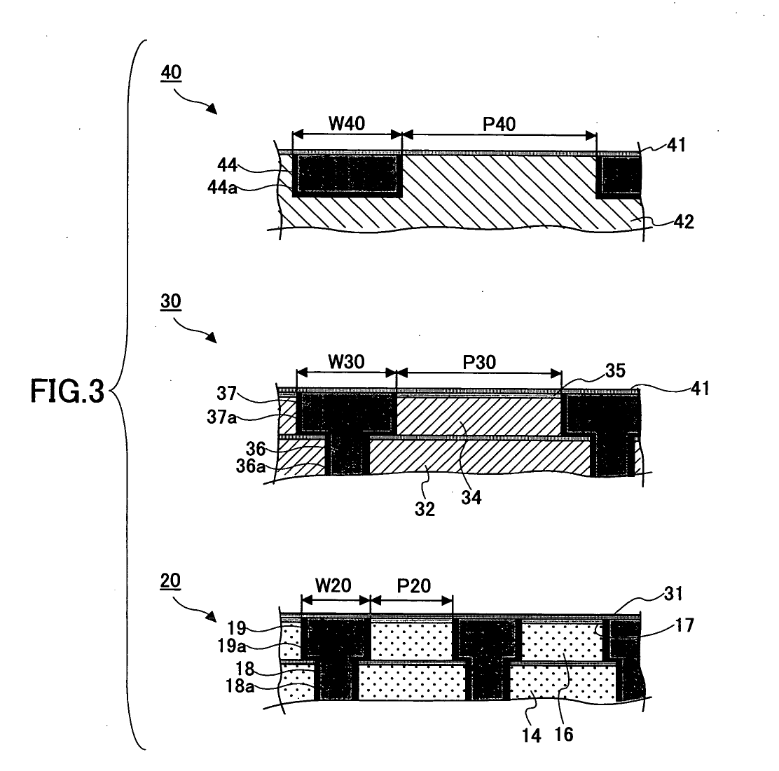

FIG. 3 is a diagram illustrating the wiring pitches of the wirings in the wiring structure 20, the wiring structure 30, and the global wiring structure 40. It is noted that in this drawing, elements that are identical to those described in relation to FIG. 2 are assigned the same reference numerals and their descriptions are omitted.

In FIG. 3, the wiring width W20 of the wiring structure 20 is arranged to be narrower than the wiring width W30 of the wiring structure 30. Also, the wiring pitch P20 of the Cu wiring 19 in the wiring structure 20 is arranged to be narrower than the wiring pitch P30 of the wiring 37 in the wiring structure 30.

As is illustrated in this example, in a lower wiring layer such as the wiring structure 20 that has a narrow wiring width and a narrow wiring pitch for adjacent wiring portions, an insulating film such as a porous insulating film having a dielectric constant that is lower than that of an organic film is preferably used as the inter-layer insulating layer in order to reduce the inter-wiring parasitic capacitance and increase the operating speed of the semiconductor device.

Also, the wiring width W40 of the global wiring structure 40 is arranged to be wider than the wiring width W30 of the wiring structure 30. The wiring pitch P40 of the Cu wiring 44 of the wiring structure 40 is arranged to be wider than the wiring pitch 30 of the Cu wiring 37 of the wiring structure 30.

As is illustrated in this example, in an upper wiring layer of a semiconductor device such as the global wiring structure 40, the wiring pitch is arranged to be relatively wide, and the inter-layer insulating film is arranged to take up a relatively large proportion of the wiring structure. If an organic film having a high fracture toughness value but low mechanical strength is used as the inter-layer insulating film in such a wiring structure, the global wiring structure may not have adequate mechanical strength. Accordingly, a film with a relatively high level of mechanical strength such as a SiO₂ film or a SiOC film is preferably used as the inter-layer insulating film of the global wiring structure 40.

Also, it is noted that in an upper wiring layer such as the global wiring structure 40, the wiring resistance value does not have as great an influence on the wiring delay as the lower wiring layers, and thereby, according to an embodiment, the Cu wiring 44 may be replaced by Al wiring, for example.

### Second Embodiment

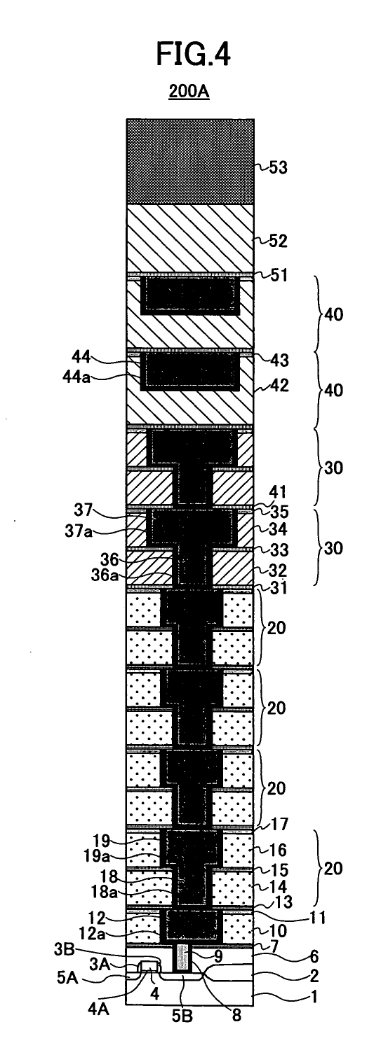

In the following, a modification example of the semiconductor device 200 of FIG. 2 is described with reference to FIG. 4. It is noted that in FIG. 4, elements that are identical to those described in relation to FIG. 2 are assigned the same reference numerals and their descriptions are omitted.

As is shown in FIG. 4, the semiconductor device 200A as a modification example of the semiconductor device 200 includes two layers of the wiring structure 30 including the shock absorbing layer.

As can be appreciated from this example, the number of layers of the wiring structure including an organic film is not limited to one layer, and plural layers of such wiring structure including the shock absorbing layer may be included in the semiconductor device. In the present embodiment, effects similar to those obtained in the first embodiment may be obtained, and additionally, the impact of stress may be further reduced compared to the first embodiment.

As is described in relation to the first embodiment, in the upper wiring layer such as the global wiring structure 40 of the semiconductor device 200A, the wiring pitch is arranged to be wide and the inter-layer insulating film is arranged to take up a large proportion of the wiring structure. Accordingly, an insulating film with a high level of mechanical strength such as a SiO₂ film or a SiOC film is preferably used as the inter-layer insulating film of the global wiring structure 40.

Also, in a lower wiring layer such as the wiring structure 20 that has a narrow wiring width and a narrow wiring pitch between adjacent wirings, an insulating film such as a porous insulating film that has a dielectric constant that is lower than that of an organic film is preferably used as the inter-layer insulating film in order to reduce the inter-wiring parasitic capacitance and increase the operating speed of the semiconductor device.

### Third Embodiment

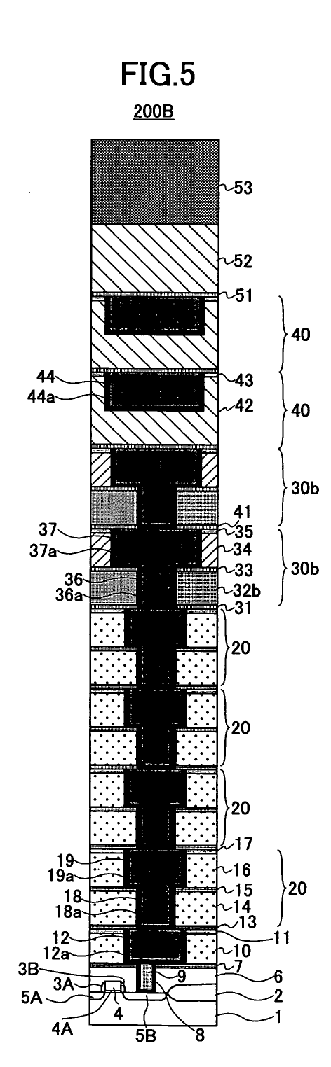

In the following, another modified example of the semiconductor device 200 of FIG. 2 is described with reference to FIG. 5. It is noted that in FIG. 5, elements that are identical to those described in relation to FIG. 2 are assigned the same reference numerals and their descriptions are omitted.

As is shown in FIG. 5, in the semiconductor device 200B as a modification example of the semiconductor device 200, the wiring structure 30 is replaced by a wiring structure 30b. In the wiring structure 30b the inter-plug insulating film 32 of the wiring structure 30 that is made of an organic film is replaced by an inter-plug insulating film 32b that is made of a SiOC film.

In the present embodiment, when stress is applied to the semiconductor device 200B, the inter-wiring insulating film 34 acts as the shock absorbing layer for reducing the impact of the stress applied to the semiconductor device 200B so as to obtain effects similar to that realized in the semiconductor device 200 according to the first embodiment.

Also, in the present embodiment, since the inter-plug insulating film 32b is made of a SiOC film, which has greater mechanical strength or hardness compared to an organic film, when stress is applied to the semiconductor device 200B, the stress exerted onto the inter-wiring insulating film 10, the inter-plug insulating film 14, and the inter-wiring insulating film 16 that are realized by a porous insulating film with a low dielectric constant may be reduced by the inter-plug insulating film 32b.

In the present embodiment, the impact of stress applied to the semiconductor device 200B may be reduced by the inter-wiring insulating film 34, and breakage and exfoliation of the inter-wiring insulating film 10, the inter-plug insulating film 14, and the inter-wiring insulating film 16 may be further prevented by the inter-plug insulating film 32b.

It is noted that a SiO₂ film may be used in place of the SiOC film as the inter-plug insulating film 32b to obtain similar effects as is described above.

In other alternative embodiments, the inter-wiring insulating film may be made of a SiO₂ film or a SiOC film, for example, and the inter-plug insulating film may be made of an organic insulating film.

### Fourth Embodiment

In the following, another modified example of the semiconductor device 200 of FIG. 2 is described with reference to FIG. 6. It is noted that in FIG. 6, elements that are identical to those described in relation to FIG. 2 are assigned the same reference numerals and their descriptions are omitted.

As is shown in FIG. 6, in the semiconductor device 200C as a modification example of the semiconductor device 200, the Cu wiring is formed through the single damascene method. In such a case, the Cu wiring and the Cu plug are electrically connected via a barrier film.

For example, a via hole is formed through etching at the protective film 13, the inter-plug insulating film 14, and the protective film 15, and a Cu plug 18c and a barrier film 18ac surrounding the Cu plug 18c are arranged in the via hole. The Cu plug 18c is electrically connected to the Cu wiring 12 via the barrier film 18ac.

A wiring trench is formed through etching at the inter-wiring insulating film 16 and the cap film 17, and Cu wiring 19c and a barrier film 19ac surrounding the Cu wiring 19c are arranged in the wiring trench. The Cu wiring 19c is electrically connected to the Cu plug 18c via the barrier film 19ac.

Similarly, a via hole is formed through etching at the protective film 33, the inter-plug insulating film 32 and the protective film 33, and a Cu plug 36c and a barrier film 36ac surrounding the Cu plug 36c are arranged in the via hole. The Cu plug 36c is electrically connected to the Cu wiring 19 via the barrier film 36ac.

A wiring trench is formed through etching at the inter-wiring insulating film 34 and the cap film 35, and Cu wiring 37c and a barrier film 37ac surrounding the Cu wiring 37c are arranged in the wiring trench. The Cu wiring 37c is electrically connected to the barrier film 37ac via the Cu plug 36c.

It is noted that a method of fabricating the wiring structure as is described above through the single damascene method is described below with reference to FIGS. 8A through 8P.

### Fifth Embodiment

In the following, a method of fabricating the semiconductor device 200 shown in FIG. 2 is described.

FIGS. 7A through 7P are diagrams illustrating the steps for fabricating the semiconductor device 200. It is noted that in these drawings, elements that are identical to those previously described are assigned the same numerical references, and their descriptions are omitted.

In the step shown in FIG. 7A, the dispersion layers 5A, 5B, and the gate electrode 4 arranged on the gate insulating film 4A and including side wall insulating films 3A and 3B are formed at the device region isolated by the device isolation film 2, which is arranged on the Si substrate 1.

Then, in the step shown in FIG. 7B, the inter-plug insulating film 6 that is made of a PSG film (phosphosilicate glass film), for example, is formed with a thickness of 1.5 μm on the Si substrate 1 at a substrate temperature of 600° C. to cover the gate electrode 4 and the side wall insulating films 3A and 3B, after which the film is smoothed out in a CMP process.

Then, the protective film 7 made of a SiC film (e.g., ESL3 (registered trademark) by Novellus Systems, Inc.) is formed on the smoothed inter-plug insulating film 6, after which a mask having a resist pattern is arranged on the protective film 7 and a contact hole is formed through dry etching. Then, the barrier film 8 made of TiN is arranged at the contact hole through sputtering, after which WF₆ and hydrogen are combined and reduced at the contact hole to form the contact plug 9 made of W. Then, the contact plug 9 is smoothed and polished by a CMP process to obtain a structure as is shown in FIG. 7B.

Then, in the step shown in FIG. 7C, the inter-wiring insulating film 10 that may be made of a porous insulating film such as a porous silica film (e.g., NCS (registered trademark) by Catalysts and Chemical Industries Co., Ltd.) is formed on the smoothed protective film 7 and the contact plug 9 with a thickness of 150 nm, and the cap film 11 made of a SiO₂ film with a thickness of 100 nm is laminated on the inter-wiring insulating film 10.

Then, in the step shown in FIG. 7D, a wiring trench 10A is formed through plasma dry etching, for example, using a wiring patterned resist layer that is arranged on the cap film 11 as a mask.

Then, in the step shown in FIG. 7E, the barrier film 12a made of TaN that acts as a Cu dispersion barrier for the porous insulating film 10 is formed at the wiring trench 10A with a thickness of 30 nm through sputtering, and a Cu seed layer 12b that acts as an electrode upon performing an electroplating process is formed with a thickness of 30 nm through sputtering.

Then, in the step shown in FIG. 7F, Cu is implanted into the wiring trench through electroplating, after which portions of the Cu and the barrier film other than those at the wiring trench are removed through CMP to realize the Cu wiring structure 12 as is shown in FIG. 7F.

Then, the Cu plug 18 and the Cu wiring 19, or the Cu plug 36 and the Cu wiring 37 may be formed on the structure of FIG. 7F through the dual damascene method involving simultaneous formation of the Cu plug and the Cu wiring, or the single damascene method involving individual formation of the Cu plug and the Cu wiring, for example.

In the following, a case of implementing the dual damascene method is described with reference to FIGS. 7G through 7P.

In the step shown in FIG. 7G, the protective film 13 made of a SiC film (e.g., ESL3 (registered trademark) by Novellus Systems, Inc.) for preventing Cu dispersion is formed with a thickness of 50 nm on the structure shown in FIG. 7F through a plasma CVD process, for example, and the inter-plug insulating film 14 made of the same porous silica film as that of the inter-wiring insulating film 10 is formed with a thickness of 170 nm on the protective film 13.

Then, the protective film 15, which is used as an etching stopper film upon forming the wiring trench is formed on the inter-plug insulating film 14 with a thickness of 50 nm, after which the inter-wiring insulating film 16 made of the same porous silica film as that of the inter-plug insulating film 14 is formed on the protective film 15 with a thickness of 150 nm, and the cap film 17 made of a SiO₂ film is formed on the inter-wiring insulating film 16 with a thickness of 100 nm. It is noted that in an alternative embodiment, the etching stopper film; namely, the protective film 15, may be omitted.

Then, in the step shown in FIG. 7H, a via pattern is formed on the cap film 17 with a resist, and the resist is used as a mask to form a via hole 14A through plasma dry etching, for example. In this case, since the cap film 17, the inter-wiring insulating film 16, the protective film 15, the inter-plug insulating film 14, and the protective film 13 may have different film compositions, the etching gas or the gas ratio used for etching the films may be changed accordingly upon performing the dry etching on the films to successively etch the cap film 17, the inter-wiring insulating film 16, the protective film 15, the inter-plug insulating film 14 and the protective film 13 in this order.

Then, in the step shown in FIG. 7I, a wiring trench 16A is formed through plasma dry etching, for example, using a resist having a Cu wiring pattern as a mask.

Then, in the step shown in FIG. 7J, the barrier films 18a and 19a made of TaN as dispersion barrier films for preventing dispersion of Cu are formed with thicknesses of 30 nm at the inner walls of the via hole 14A and the wiring trench 16A, respectively. Then, seed layers 18b and 19b that act as electrodes upon performing a Cu electroplating process are formed with thicknesses of 30 nm through sputtering on the barrier films 18a and 19a, respectively.

Then, in the step shown in FIG. 7K, Cu is implanted into the via hole 14A and the wiring trench 16A through electroplating, and portions of the Cu and barrier film other than those corresponding to the wiring pattern portion are removed through CMP to form the Cu wiring 19 and the Cu plug 18. In this way, the wiring structure 20 is realized. By repeating the steps shown in FIGS. 7G through 7K, plural layers of the wiring structure 20 may be formed. In the case of forming the semiconductor device 200 shown in FIG. 2, the steps of FIGS. 7G through 7K are repeated four times to form five layers of wiring structures including the wiring structure formed in the steps shown in FIGS. 7C through 7F.

In the following, a process of laminating the wiring structure 30 on the wiring structure 20 is described with reference to FIGS. 7L through 7P.

In the step shown in FIG. 7L, the protective film 31 made of a SiN film, for example, that acts as a barrier for preventing Cu dispersion is formed with a thickness of 50 nm on the cap film 17 and the Cu wiring 19 of the wiring structure 20, and the inter-plug insulating film 32 made of and organic insulating film having a high fracture toughness value such as allyl ester (e.g., SiLK-J 350 (registered trademark) by The Dow Chemical Company) having a fracture toughness resistance of 25 is formed on the protective film 31.

Then, the protective film 33 used as an etching stopper film upon forming a wiring trench is formed with a thickness of 50 nm on the inter-plug insulating film 32, after which the inter-wiring insulating film 34 made of the same organic insulating film as that of the inter-plug insulating film 32 is formed on the protective film 33, and the cap film 35 made of a SiO₂ film is formed with a thickness of 100 nm on the inter-wiring insulating film 34. In an alternative embodiment, the inter-plug insulating film 32 and the inter-wiring insulating film 34 may be arranged to have a combined film thickness of 450 nm, and the etching stopper film, namely, the protective film 33 may be omitted, for example.

Then, in the step shown in FIG. 7M, a via pattern is formed on the cap film 35 with a resist, and the resist is used as a mask to form a via hole 32A through dry etching using plasma, for example.

Then, in the step shown in FIG. 7N, a wiring trench 34A is formed through plasma dry etching using a resist having a Cu wiring pattern as a mask.

Then, in the step shown in FIG. 70, the barrier films 36a and 37a made of TaN that act as dispersion barrier films for preventing dispersion of Cu are formed with thicknesses of 30 nm at the inner walls of the via hole 32A and the wiring trench 34A, respectively. Then, Cu seed layers 36b and 37b that act as electrodes upon performing a Cu electroplating process are formed with thicknesses of 30 nm through sputtering on the barrier films 36a and 37a.

Then, in the step shown in FIG. 7P, Cu is implanted into the via hole 32A and the wiring trench 34A through electroplating, and portions of the Cu and the barrier film other than those corresponding to the wiring portion are removed through CMP so that the Cu wiring 36 and the Cu plug 37 may be formed. In this way, the wiring structure 30 is realized.

Then, the global wiring structure 40 including a SiO₂ film as the inter-layer insulating film is formed on the wiring structure 30, after which the protective film 51 and the cap film 52 made of a SiO₂ film are formed on the global wiring structure 40, and a pad 53 made of Al is formed on the cap film 52 to realize the semiconductor device 200.

It is noted that the semiconductor device 200 fabricated in the above-described manner was tested by repeatedly performing a 30-minute-long thermal process at a temperature of 400° C. five times. However, neither breakage nor exfoliation of the inter-layer insulating films was detected in the wiring structure of the tested semiconductor device 200.

As a comparison example, a similar test involving repeatedly performing the 30-minute-long thermal process at a temperature of 400° C. five times was conducted on a semiconductor device having a structure generally identical to that of the semiconductor device 200 but using porous silica films of the same material as the inter-plug insulating film 14 and the inter-wiring insulating film 16 instead of the inter-plug insulating film 32 and the inter-wiring insulating film 34 of the semiconductor device 200. In this case, breakage occurred at the porous silica films, and exfoliation of the inter-plug insulating film 14 and the protective film 13 was detected.

### Sixth Embodiment

In the following, a method of fabricating the semiconductor device 200B shown in FIG. 5 is described. The steps for fabricating the semiconductor device 200B are generally identical to the steps for fabricating the semiconductor device 200. However, in the step shown in FIG. 7L, the inter-plug insulating film 32b made of a SiOC film (e.g., CORALPORA (registered trademark) by Novellus Systems, Inc.) is formed instead of the inter-plug insulating film 32 made of an organic film, and in the step shown in FIG. 7M, the etching gas for etching the via hole is changed according to the material used for the inter-plug insulating film 32b. Also, the steps shown in FIGS. 7L through 7P are repeated two times to form two layers of the wiring structure 30b, for example. The rest of the steps for fabricating the semiconductor device 200B may be identical to the steps for fabricating the semiconductor device 200.

It is noted that the semiconductor device 200B fabricated in the above-described manner was tested by repeatedly performing a 30-minute-long thermal process at a temperature of 400° C. five times; however, breaks and exfoliation were not detected in the wiring structure.

### Seventh Embodiment

It is noted that the structure formed through the dual damascene process as is illustrated by FIGS. 7G through 7P may alternatively be formed through a single damascene process as is shown in FIGS. 8A through 8P. In the case of implementing the single damascene method, the semiconductor device 200C as is shown in FIG. 6 may be fabricated to obtain effects similar to those obtained by performing the dual damascene process. In the following, a method for fabricating the semiconductor device 200C using the single damascene method is described with reference to FIGS. 8A through 8P. It is noted that in these drawings, elements that are identical to those described above are assigned the same numerical references, and their descriptions are omitted.

It is noted that the steps shown in FIGS. 7A through 7F for fabricating the semiconductor device 200 are also used for fabricating the semiconductor device 200C. Then, in the step shown in FIG. 8A, the protective film 13 made of a SiC film (e.g., ESL3 (registered trademark) by Novellus Systems, Inc.) for preventing Cu dispersion is formed with a thickness of 50 nm through plasma CVD, for example, the inter-plug insulating film 14 made of the same porous silica film as that of the inter-wiring insulating film 10 is formed with a thickness of 170 nm on the protective film 13, and the protective film 15 is formed with a thickness of 50 nm on the inter-plug insulating film 14.

Then, in the step shown in FIG. 8B, a via pattern is formed on the protective film 15 with a resist, and the resist is used as a mask to form the via hole 14A through dry etching using plasma, for example.

Then, in the step shown in FIG. 8C, the barrier film 18ac made of TaN acting as a barrier for preventing Cu dispersion is formed with a thickness of 30 nm at the inner wall of the via hole 14A. Then, the Cu seed layer 18bc acting as an electrode upon performing an electroplating process is formed with a thickness of 30 nm on the barrier film 18ac through sputtering.

Then, in the step shown in FIG. 8D, Cu is implanted into the via hole 14A through electroplating, and portions of the barrier film and the Cu other than those at the via hole are removed to realize the Cu plug 18c.

Then, in the step shown in FIG. 8E, the inter-wiring insulating film 16 made of the same porous silica film as that of the inter-plug insulating film 14 is formed with a thickness of 150 nm on the protective film 15 and the Cu plug 18c, and the cap film 17 made of a SiO₂ film is formed with a thickness of 100 nm on the inter-wiring insulating film 16.

In the step shown in FIG. 8F, a resist having a Cu wiring pattern is used as a mask to perform dry etching using plasma, and the wiring trench 16A is formed as a result.

Then, in the step shown in FIG. 8G, the barrier film 19ac made of TaN acting as a barrier for preventing Cu dispersion is formed with a thickness of 30 nm at the inner wall of the wiring trench 16A. Then, the seed layer 19bc acting as an electrode upon performing Cu electroplating is formed with a thickness of 30 nm on the barrier film 19ac through sputtering.

Then, in the step shown in FIG. 8H, Cu is implanted into the wiring trench 16A through electroplating, and portions of the Cu and the barrier film other than those corresponding to the wiring portion are removed through CMP to form the Cu wiring 19c. In this way, the wiring structure 20c is realized. By repeating the steps of FIGS. 8A through 8H, plural layers of the wiring structure 20c may be formed. In the case of the semiconductor device 200C, the steps of FIGS. 8A through 8H are repeated four times to form five layers of wiring structures including the wiring structure formed by performing the steps of FIGS. 7C through 7F.

In the following, the process of laminating the wiring structure 30c on the above wiring structure 20c is described with reference to FIGS. 8I through 8P.

In the step shown in FIG. 8I, the protective film 31 made of a SiN film for preventing Cu dispersion is formed with a thickness of 50 nm on the cap film 17 and the Cu wiring 19c through plasma CVD, for example. Then, the inter-plug insulating film 32b made of a SiOC film (e.g., CORALPORA (registered trademark) by Novellus Systems, Inc.) is formed with a thickness of 200 nm on the protective film 31, and the protective film 33 is formed with a thickness of 50 nm on the inter-plug insulating film 32b. It is noted that in an alternative embodiment, the protective film 33 may be omitted.

Then, in the step shown in FIG. 8J, a via pattern is formed on the protective film 33 with a resist, and the resist is used as a mask to perform dry etching with F plasma so that the via hole 32bA may be formed.

Then, in the step shown in FIG. 8K, the barrier film 36ac made of TaN acting as a barrier for preventing Cu dispersion is formed with a thickness of 30 nm at the inner wall of the via hole 32bA. Then, the Cu seed layer 36bc that acts as an electrode upon performing Cu electroplating is formed with a thickness of 30 nm on the barrier film 36ac through sputtering.

Then, in the step shown in FIG. 8L, Cu is implanted into the via hole through electroplating, and portions of the Cu and the barrier other than those at the via hole are removed through CMP to form the Cu plug 36c.

Then, in the step shown in FIG. 8M, the inter-wiring insulating film 34 made of an organic film with a high fracture toughness value such as allyl ester (e.g., SiLK-J150 (registered trademark) by The Dow Chemical Company) is formed with a thickness of 170 nm on the protective film 33 and the Cu plug 36c, and the cap film 35 made of a SiO₂ film is formed with a thickness of 100 nm on the inter-wiring insulating film 34.

Then, in the step shown in FIG. 8N, a resist having the Cu wiring pattern is used as a mask to perform dry etching using plasma to form the wiring trench 34A.

Then, in the step shown in FIG. 80, the barrier film 37ac made of TaN acting as a barrier for preventing Cu dispersion is formed with a thickness of 30 nm at the inner wall of the wiring trench 34A. Then, the Cu seed layer 37bc that acts as an electrode upon performing the Cu electroplating process is formed with a thickness of 30 nm on the barrier film 37ac through sputtering.

Then, in the step of FIG. 8P, Cu is implanted into the wiring trench 34A through electroplating, and the portions of the Cu and the barrier film other than those corresponding to the wiring portions are removed through CMP so that the Cu wiring 37c may be formed. In this way, the wiring structure 30c may be realized.

In the case of fabricating the semiconductor device 200C, the steps of FIGS. 8A through 8H are repeated two times so that two layers of the wiring structure 30c may be formed.

The rest of the steps performed for fabricating the semiconductor device 200C are identical to those performed for fabricating the semiconductor device 200.

Upon testing the semiconductor device 200C fabricated in the above-described manner by performing a 30-minute-long thermal process at a temperature of 400° C. five times, breakage and exfoliation were not detected in the wiring structures.

It is noted that the number of layers of the wiring structure that uses a porous insulating film as the inter-layer insulating film, the number of layers of the wiring structure that uses a shock absorbing layer with a high fracture toughness value as the inter-layer, and the number of layers of the upper layer wiring structure; namely, the global wiring structure, may be arbitrarily adjusted as is necessary or desired.

Although the present invention is shown and described with respect to certain preferred embodiments, it is obvious that equivalents and modifications will occur to others skilled in the art upon reading and understanding the specification. The present invention includes all such equivalents and modifications, and is limited only by the scope of the claims.

What is claimed is:

1. A semiconductor device, comprising:
a substrate;
a first wiring structure arranged on the substrate which first wiring structure includes a first insulating layer and a first wiring layer arranged within the first insulating layer;
a second wiring structure arranged on the first wiring structure which second wiring structure includes a second insulating layer including a shock absorbing layer made of an insulating film and a second wiring layer arranged within the second insulating layer; and
a third wiring structure arranged on the second wiring structure which third wiring structure includes a third insulating layer and a third wiring layer arranged within the third insulating layer;
wherein a second fracture toughness value of the shock absorbing layer is greater than a first fracture toughness value of the first insulating film and a third fracture toughness value of the third insulating film.

2. The semiconductor device as claimed in claim 1, wherein
the second insulating layer includes another insulating film that is harder than the shock absorbing layer.

3. The semiconductor device as claimed in claim 2, wherein
the second wiring layer includes a trench wiring layer that is arranged within the shock absorbing layer and a via wiring layer that is arranged within the other insulating film.

4. The semiconductor device as claimed in claim 1, wherein
the first wiring layer and the second wiring layer include Cu.

5. The semiconductor device as claimed in claim 1, wherein
the third wiring layer includes at least one of Cu and Al.

6. The semiconductor device as claimed in claim 1, wherein
a second wiring pitch of the second wiring layer is greater than a first wiring pitch of the first wiring layer.

7. The semiconductor device as claimed in claim 1, wherein
a third wiring pitch of the third wiring layer is greater than a second wiring pitch of the second wiring layer.

8. The semiconductor device as claimed in claim 1, wherein
the shock absorbing layer includes an organic insulating film.

9. The semiconductor device as claimed in claim 8, wherein
the organic insulating film includes at least one of allyl ester and benzocyclobutene.

10. The semiconductor device as claimed in claim 1, wherein
the first insulating layer includes a porous insulating film.

11. The semiconductor device as claimed in claim 10, wherein
the porous insulating film includes at least one of a porous silica film, a porous SiO₂ film, and a porous organic film.

12. The semiconductor device as claimed in claim 2, wherein
the other insulating film includes at least one of a SiO₂ film and a SiOC film.

13. A semiconductor device, comprising:
a substrate;
a first wiring structure arranged on the substrate which first wiring structure includes a first insulating layer and a first Cu wiring layer arranged within the first insulating layer; and
a second wiring structure arranged on the first wiring structure which second wiring structure includes a second insulating layer including a shock absorbing layer made of an insulating film and a second Cu wiring layer arranged within the second insulating layer;
wherein a second fracture toughness value of the shock absorbing layer is greater than a first fracture toughness value of the first insulating layer.

14. The semiconductor device as claimed in claim 13, further comprising:
a third wiring structure arranged on the second wiring structure which third wiring structure includes a third insulating layer and a third wiring layer arranged within the third insulating layer.

15. The semiconductor device as claimed in claim 14, wherein
the second fracture toughness value of the shock absorbing layer is greater than a third fracture toughness value of the third insulating.

16. The semiconductor device as claimed in claim 13, wherein
the second insulating layer includes another insulating film that is harder than the shock absorbing layer.

17. The semiconductor device as claimed in claim 16, wherein
the second wiring layer includes a trench wiring layer that is arranged within the shock absorbing layer and a via wiring layer that is arranged within the other insulating film.

18. The semiconductor device as claimed in claim 14, wherein
the third wiring layer includes at least one of Cu and Al.

19. The semiconductor device as claimed in claim 13, wherein
a second wiring pitch of the second wiring layer is greater than a first wiring pitch of the first wiring layer.

20. The semiconductor device as claimed in claim 14, wherein
a third wiring pitch of the third wiring layer is greater than a second wiring pitch of the second wiring layer.

21. The semiconductor device as claimed in claim 13, wherein
the shock absorbing layer includes an organic insulating film.

22. The semiconductor device as claimed in claim 21, wherein
the organic insulating film includes at least one of allyl ester and benzocyclobutene.

23. The semiconductor device as claimed in claim 13, wherein
the first insulating layer includes a porous insulating film.

24. The semiconductor device as claimed in claim 23, wherein
the porous insulating film includes at least one of a porous silica film, a porous SiO₂ film, and a porous organic film.

25. The semiconductor device as claimed in claim 16, wherein
the other insulating film includes at least one of a SiO₂ film and a SiOC film.
